(19) United States
(12) Patent Application Publication
(10) Pub. No.: US 2025/0385101 A1
(43) Pub. Date: Dec. 18, 2025

(54) EXTREME ULTRAVIOLET (EUV) ACTIVATED UNDERLAYER

(71) Applicant: Applied Materials, Inc., Santa Clara, CA (US)

(72) Inventors: NANCY FUNG, Livermore, CA (US); CHI-I LANG, Cupertino, CA (US); MICHAEL STOLFI, Clifton Park, NY (US); HIDEYUKI KANZAWA, Halfmoon, NY (US); LEQUN LIU, San Jose, CA (US)

(21) Appl. No.: 19/215,201

(22) Filed: May 21, 2025

Related U.S. Application Data
(60) Provisional application No. 63/660,960, filed on Jun. 17, 2024.

(51) Int. Cl. H01L 21/311; G03F 1/22; G03F 7/00; G03F 7/16

(52) U.S. Cl. CPC H01L 21/31144; G03F 1/22; G03F 7/167; G03F 7/70033

(57) ABSTRACT

Embodiments described herein relate to a method that includes forming a patterning stack over a substrate, wherein the patterning stack includes an underlayer over the substrate that includes an extreme ultraviolet (EUV) sensitive material with —OH terminated chains, and a resist layer over the underlayer. The method further includes exposing regions of the patterning stack with EUV electromagnetic radiation, and increasing a temperature of the patterning stack, wherein OH and/or H₂O is released from exposed regions of the underlayer and diffuses into the resist layer. The method may also include developing the resist layer.

### CROSS-REFERENCE TO RELATED APPLICATIONS

This application claims the benefit of U.S. Provisional Application No. 63/660,960, filed on Jun. 17, 2024, the entire contents of which are hereby incorporated by reference herein.

### BACKGROUND

### 1) Field

Embodiments relate to the field of semiconductor manufacturing and, in particular, extreme ultraviolet (EUV) patterning with an underlayer that is EUV activated.

### 2) Description of Related Art

Extreme ultraviolet (EUV) photoresist materials generally have low efficiency and require high dosages in order to obtained a desired contrast between exposed and unexposed regions. Further, a low EUV dose typically results in higher line edge roughness (LER), higher line width roughness (LWR), and poor local critical dimension uniformity (LCDU). Increasing the dose reduces throughput, which increases the overall cost of the lithography process.

Accordingly, attempts to increase EUV efficiency of photoresist materials is of particular interest to the industry. Different material systems, such as metal oxide resists (MORs), chemically amplified resists (CARs), and the like have been developed to improve contrast after exposure. Some approaches have also proposed the use of underlayer materials in order to improve the efficiency of the photoresist material. In some instances, the underlayer also reacts under a stimulus (e.g., heat, electromagnetic radiation, etc.) in order to drive additional species from the underlayer into the photoresist layer to improve chemical conversion of the photoresist layer.

### SUMMARY

Embodiments described herein relate to a method that includes forming a patterning stack over a substrate, wherein the patterning stack includes an underlayer over the substrate that includes an extreme ultraviolet (EUV) sensitive material with —OH terminated chains, and a resist layer over the underlayer. The method further includes exposing regions of the patterning stack with EUV electromagnetic radiation, and increasing a temperature of the patterning stack, wherein OH and/or H₂O is released from exposed regions of the underlayer and diffuses into the resist layer. The method may also include developing the resist layer.

Embodiments described herein include a patterning stack for extreme ultraviolet (EUV) lithography that includes a substrate with an underlayer over the substrate, wherein the underlayer includes a first EUV sensitive material with —OH terminated chains. The patterning stack may also include a resist layer over the underlayer, wherein the resist layer is a second EUV sensitive material.

Embodiments described herein relate to a method that includes forming a patterning stack over a substrate, wherein the patterning stack includes an underlayer over the substrate, wherein the underlayer includes an extreme ultraviolet (EUV) sensitive material including silicon, oxygen, carbon, and hydrogen with —OH terminated chains. The patterning stack may also include a resist layer over the underlayer, wherein the resist layer is a metal oxide resist (MOR). The method may include exposing regions of the patterning stack with EUV electromagnetic radiation, and curing the patterning stack, wherein exposure and curing drives a silanol condensation cross-linking process in the underlayer that releases OH and/or H₂O that diffuses into the resist layer. The method may also include developing the resist layer.

### BRIEF DESCRIPTION OF THE DRAWINGS

FIG. 1A is a cross-sectional illustration of a substrate with a patterning stack that includes an underlayer and a resist layer, in accordance with an embodiment.

FIG. 1B is a cross-sectional illustration of the patterning stack during an extreme ultraviolet (EUV) exposure and cure that drives global diffusion of species from the underlayer into the resist layer, in accordance with an embodiment.

FIG. 1C is a cross-sectional illustration of the patterning stack after the resist layer is patterned, in accordance with an embodiment.

FIG. 1D is a cross-sectional illustration of the patterning stack after the pattern in the resist layer is transferred into the underlayer, in accordance with an embodiment.

FIG. 2A is a cross-sectional illustration of a substrate with a patterning stack that includes an underlayer with —OH terminated chains and a resist layer, in accordance with an embodiment.

FIG. 2B is a cross-sectional illustration of the patterning stack during an EUV exposure and cure that drives local diffusion of species from the underlayer into the resist layer, in accordance with an embodiment.

FIG. 2C is a cross-sectional illustration of the patterning stack after the resist layer is patterned, in accordance with an embodiment.

FIG. 2D is a cross-sectional illustration of the patterning stack after the pattern in the resist layer is transferred into the underlayer, in accordance with an embodiment.

FIG. 3 is a Fourier transform infrared spectroscopy graph of an as deposited underlayer and after EUV exposure and cure, in accordance with an embodiment.

FIG. 4A is a schematic of an underlayer material with —OH terminations before EUV exposure, in accordance with an embodiment.

FIG. 4B is a schematic of the underlayer material after EUV exposure to initiate a cross-linking process that releases OH and/or H₂O, in accordance with an embodiment.

FIG. 5 is a flow diagram of a process for pattering a patterning stack with an underlayer that comprises-OH terminations, in accordance with an embodiment.

FIG. 6 is a cluster tool that may be used to implement a process for patterning a patterning stack with an underlayer that comprises-OH terminations, in accordance with an embodiment.

FIG. 7 illustrates a block diagram of an exemplary computer system that may be used in conjunction with a processing tool, in accordance with an embodiment.

### DETAILED DESCRIPTION

Embodiments described herein include extreme ultraviolet (EUV) patterning with an underlayer that is EUV activated. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, EUV photoresist material systems are limited due to the need for high dosages in order to obtain the desired contrast with suitable line edge roughness (LER), line width roughness (LWR), and local critical dimension uniformity (LCDU). Some attempts to augment the performance of the EUV photoresist material include adding an underlayer. The underlayer may provide chemical species that, in response to a stimulus, diffuse into the photoresist layer in order to help the chemical conversion of the photoresist material. However, existing underlayer materials result in global release of the species. This can lead to issues with increased LER and LWR, lower LCDU, and scum (i.e., residual material at the bottom of the patterned opening after development).

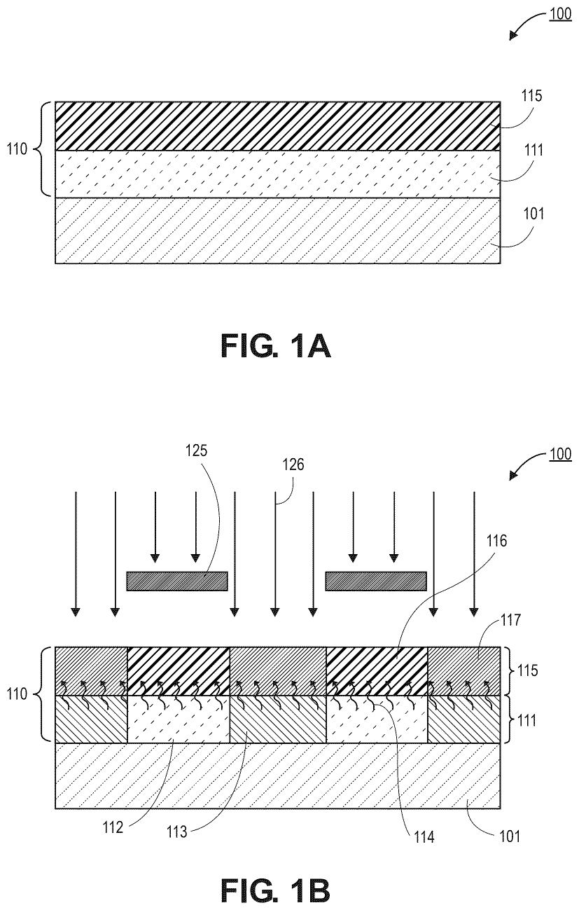

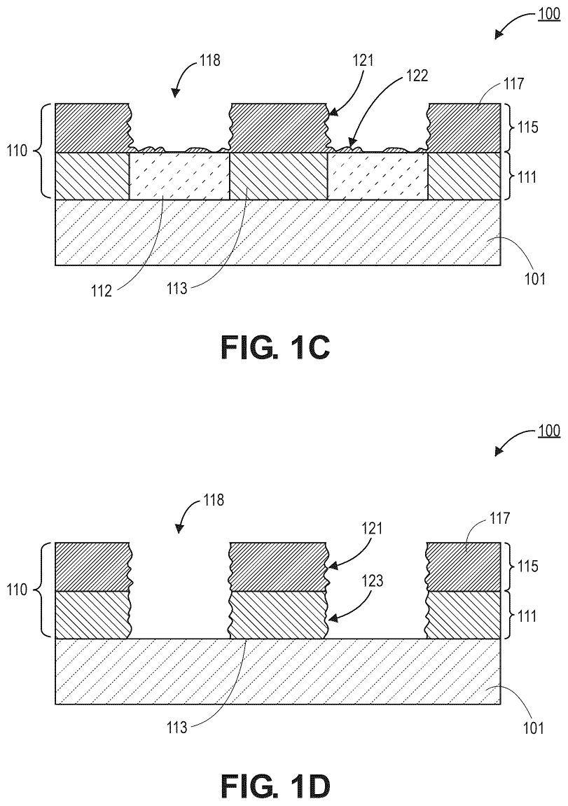

Referring now to FIGS. 1A-1D, a series of cross-sectional illustrations depicting an example of such an underlayer system with global release of species is shown, in accordance with an embodiment.

Referring now to FIG. 1A, a cross-sectional illustration of a device 100 is shown, in accordance with an embodiment. In an embodiment, the device 100 comprises a substrate 101. The substrate 101 may be a semiconductor substrate, such as a silicon wafer or the like. Though, any material (e.g., glass, ceramic, etc.) may be used for the substrate 101 in other embodiments. In an embodiment, a patterning stack 110 is provided over the substrate 101. In the illustration of FIG. 1A, the patterning stack 110 comprises an underlayer 111 and a photoresist layer 115 over the underlayer 111. Though, it is to be appreciated that the patterning stack 110 may include one or more additional layers, such as oxide layers, carbon layers, antireflective coating (ARC) layers, silicon layers, and/or the like. In some instances, the one or more additional layers may be provided between the underlayer 111 and the substrate 101.

In an embodiment, the photoresist layer 115 may be an EUV sensitive material. That is, exposure of the photoresist layer 115 to EUV electromagnetic radiation may result in a chemical reaction in the exposed regions. For example, a cross-linking reaction may be initiated by the EUV exposure. The photoresist layer 115 may include any suitable EUV photoresist material. In a particular embodiment, the photoresist layer 115 is a metal oxide resist (MOR). In some instances, the photoresist layer 115 may also be referred to as a resist layer 115 for simplicity.

In an embodiment, the underlayer 111 may be a dielectric material. For example, the underlayer 111 may comprise a carbon based polymer with oxygen and hydrogen incorporated into the carbon chains. The underlayer 111 may also be treated with a nitrogen containing process (e.g., a process comprising NH₃). The process may be a thermal process or a plasma process.

Referring now to FIG. 1B, a cross-sectional illustration of the device 100 during an EUV exposure process is shown, in accordance with an embodiment. In an embodiment, the EUV exposure process may include selectively exposing the patterning stack 110 to EUV electromagnetic radiation 126. The EUV electromagnetic radiation 126 may be blocked at certain locations by a mask 125, reticle, or the like. The portion of the EUV electromagnetic radiation 126 that reaches the patterning stack 110 results in the formation of exposed resist regions 117 and unexposed resist regions 116 in the resist layer 115. The underlayer 111 may also have exposed regions 113 and unexposed regions 112.

In some embodiments, a curing process may be implemented during and/or after the EUV exposure. For example, the curing process may include a thermal cure and/or an ultraviolet (UV) cure. In some instances, the curing process may result in the release of species 114 from the underlayer 111. As shown, the released species 114 are globally released by both the exposed regions 113 and the unexposed regions 112. The released species 114 may diffuse into the overlying resist layer 115. That is, both the exposed resist regions 117 and the unexposed resist regions 116 may receive the released species 114. Accordingly, the chemical reaction may be augmented in the entirety of the resist layer 115.

Referring now to FIG. 1C, a cross-sectional illustration of the device 100 after the resist layer 115 is developed is shown, in accordance with an embodiment. The developing process may result in the removal of the unexposed resist regions 116. However, due to the uptake of the released species 114 into the unexposed resist regions 116, the developing process may not result in a pattern 118 that meets the desired specifications. For example, sidewalls 121 of the pattern 118 may have a high roughness that leads to poor LER, LWR, and/or LCDU. Further, the developing process may not fully clear the unexposed resist regions 116 from the pattern 118. This can lead to the presence of scum 122 at the bottom of the pattern 118. The high roughness of the sidewalls 121 and the scum 122 may result in suboptimal pattern transfer into underlying layers.

Referring now to FIG. 1D, a cross-sectional illustration of the device 100 after the pattern 118 in the resist layer 115 is transferred into the underlayer 111 with an etching process is shown, in accordance with an embodiment. As shown, the underlayer 111 will also have sidewalls 123 that have a high roughness due to the high roughness of the sidewalls 121 in the resist layer 115 and the scum 122. Accordingly, the pattern 118 in the underlayer 111 is also suboptimal. As critical dimensions (CDs) continue to shrink in advanced semiconductor devices, the increases in LER and LWR, and/or decreases in LCDU will significantly impact device 100 performance.

Accordingly, embodiments disclosed herein comprise an optimized underlayer material system. Particularly, the underlayers described herein include a material composition that is tuned to selectively release species into the exposed regions of the overlying resist layer. That is, cross-linking in the unexposed regions of the overlying resist layer is not augmented by the presence of species from the underlayer. This allows for improved contrast between the exposed resist regions and the unexposed resist regions. As such, lower doses can be used to provide better LER, LWR, and/or LCDU compared to existing material systems. Additionally, residual scum at the bottom of the developed pattern in the resist layer is reduced or eliminated as a result of the improved selectivity in diffusing species from the underlayer into the overlying resist layer.

In some embodiments, the underlayer material system also comprises an EUV sensitive material. The EUV sensitive material allows for a chemical reaction to be initiated when exposed to the EUV electromagnetic radiation used to expose the resist layer. For example, the chemical reaction in the underlayer may include a cross-linking reaction. In some instances, the cross-linking reaction is a silanol condensation. The chemical reaction may result in the release of OH and/or H₂O molecules.

In some embodiments, the underlayer material may comprise-OH terminated chains. More particularly, the underlayer material may comprise a polymer comprising silicon, oxygen, carbon, and hydrogen (e.g., SiOCH) with —OH terminated chains. Such a polymer may sometimes be referred to as being a dielectric material and/or may be referred to as a flowable film. A flowable film may refer to a material layer that is soft with a low modulus and viscosity. In some embodiments, the underlayer material may not be treated with a process comprising nitrogen (e.g., NHs gas). That is, the underlayer material may be free from nitrogen or substantially free of nitrogen (e.g., less than 1% nitrogen by weight). Removing the nitrogen from the underlayer may improve performance of the overlying resist layer since the nitrogen may inhibit the cross-linking reaction in the resist layer.

In an embodiment, the underlayer may be tuned to selectively release the species (e.g., OH and/or H₂O) into the resist layer through a combination of the EUV exposure and curing process. In an embodiment, the underlayer may not release OH and/or H₂O at an elevated temperature in an as-deposited state (i.e., before exposure). However, after EUV exposure, the underlayer may release the OH and/or H₂O at an elevated temperature (e.g., from around 160° C. or above). Accordingly, the species is only released from the exposed regions of the underlayer, which allows diffusion of the species only into the exposed regions of the resist layer that directly overly the exposed regions of the underlayer. The addition of the species to only the exposed regions of the resist layer allows for an improved contrast between exposed regions of the resist layer and the unexposed regions of the resist layer. Further, pattern sidewall roughness and the presence of scum is reduced from the developed resist layer. In embodiments disclosed herein, the underlayer may also improve etch selectivity, LER, and/or LWR. Particularly, the EUV exposed regions of the underlayer will undergo cross-linking reactions, which will make the underlayer more etch resistant. The unexposed regions of the underlayer will not be cross-linked and are easier to each. This can lead to improved etch selectivity in addition to improved LER and/or LWR compared to existing underlayer solutions. Overall, such an underlayer material allows for reductions in the EUV dose while still maintaining low LER, low LWR, and/or high LCDU.

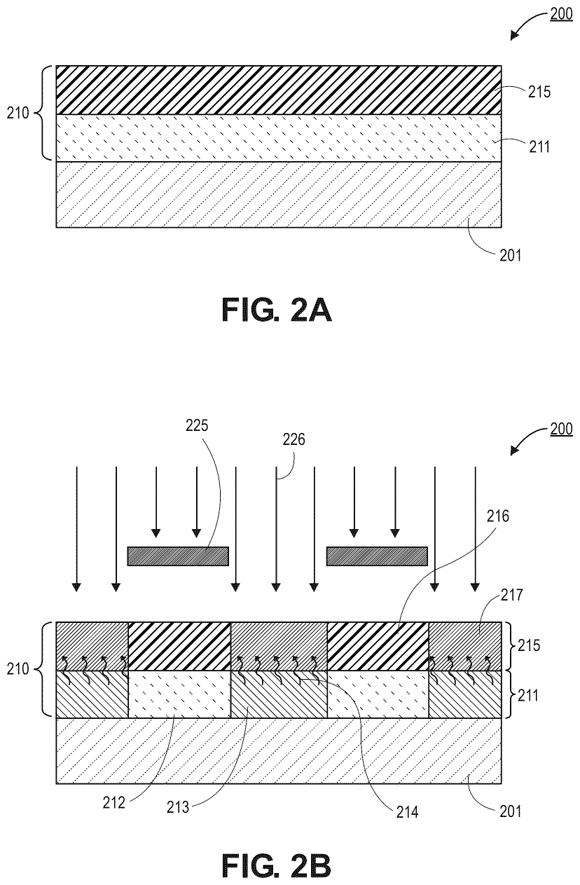

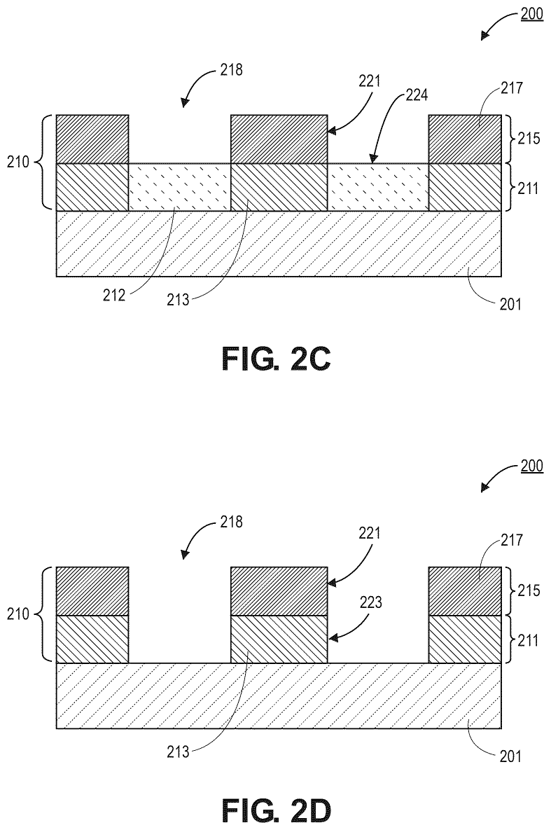

Referring now to FIGS. 2A-2D, a series of cross-sectional illustrations depicting a process for patterning a patterning stack with an underlayer and a resist layer over the underlayer is shown, in accordance with an embodiment. In an embodiment, the underlayer of the patterning stack may comprise-OH terminated chains suitable for implementing selective release of OH and/or H₂O into the exposed regions of the resist layer.

Referring now to FIG. 2A, a cross-sectional illustration of a device 200 is shown, in accordance with an embodiment. In an embodiment, the device 200 comprises a substrate 201. The substrate 201 may be a semiconductor substrate, such as a silicon wafer or the like. Though, any material (e.g., glass, ceramic, etc.) may be used for the substrate 201 in other embodiments. In an embodiment, a patterning stack 210 is provided over the substrate 201. In the illustration of FIG. 2A, the patterning stack 210 comprises an underlayer 211 and a photoresist layer 215 over the underlayer 211. Though, it is to be appreciated that the patterning stack 210 may include one or more additional layers, such as oxide layers, carbon layers, ARC layers, silicon layers, and/or the like. In some instances, the one or more additional layers may be provided between the underlayer 211 and the substrate 201.

In an embodiment, the photoresist layer 215 may be an EUV sensitive material. That is, exposure of the photoresist layer 215 to EUV electromagnetic radiation may result in a chemical reaction in the exposed regions. For example, a cross-linking reaction may be initiated by the EUV exposure. The photoresist layer 215 may include any suitable EUV photoresist material. In a particular embodiment, the photoresist layer 215 is a MOR, such as a tin-oxide based resist material. In some instances, the photoresist layer 215 may also be referred to as a resist layer 215 for simplicity.

In an embodiment, the underlayer 211 may also comprises an EUV sensitive material. For example, portions of the underlayer 211 that are exposed to EUV electromagnetic radiation may undergo a chemical reaction that includes a cross-linking reaction. In some instances, the cross-linking reaction is a silanol condensation. The chemical reaction may result in the release of OH and/or H₂O molecules. More particularly, the underlayer 211 may comprise a polymer with —OH terminated chains. For example, the underlayer 211 may include a polymer comprising silicon, oxygen, carbon, and hydrogen (e.g., SiOCH) with —OH terminated chains. Such a polymer may sometimes be referred to as being a low-k dielectric material, and/or may be referred to as a flowable film.

In contrast to other existing underlayer materials, the underlayer 211 may not be treated with a process comprising nitrogen (e.g., NH₃ gas). That is, the underlayer material may be free from nitrogen or substantially free of nitrogen underlayer may improve performance of the overlying resist layer since the nitrogen may inhibit the cross-linking reaction in the resist layer. In some instances, the omission of nitrogen from the underlayer 211 may also improve adhesion between the underlayer and the resist layer 215.

In an embodiment, one or both of the underlayer 211 and the resist layer 215 may be deposited with a chemical vapor deposition (CVD) process. In the case where both the underlayer 211 and the resist layer 215 are deposited with a CVD process, a single deposition chamber may be used in order to form the underlayer 211 and the resist layer 215 over the substrate 201. Further, the use of a dry deposition process, such as CVD, allows for compositional variations through a thickness of the underlayer 211 and/or the resist layer 215. For example, a lower region of the resist layer 215 proximate to an interface with the underlayer 211 may be tuned for improved adhesion, while and upper region of the resist layer 215 may be tuned for EUV absorption and/or cross-linking efficiency.

Referring now to FIG. 2B, a cross-sectional illustration of the device 200 during an EUV exposure process is shown, in accordance with an embodiment. In an embodiment, the EUV exposure process may include selectively exposing the patterning stack 210 to EUV electromagnetic radiation 226. The EUV electromagnetic radiation 226 may be blocked at certain locations by a mask 225, reticle, or the like. The portion of the EUV electromagnetic radiation 226 that reaches the patterning stack 210 results in the formation of exposed resist regions 217 and unexposed resist regions 216 in the resist layer 215. The underlayer 211 may also have exposed regions 213 and unexposed regions 212. For example, the exposed regions 213 may be cross-linked (e.g., through a silanol condensation reaction).

In some embodiments, a curing process may be implemented during and/or after the EUV exposure. For example, the curing process may include a thermal cure and/or an ultraviolet (UV) cure. In some instances, the curing process may improve the release of species 214 from the underlayer 211. As shown, the released species 214 are selectively released from the underlayer 211, with only the exposed regions 213 releasing the species 214. In a particular embodiment, the species 214 comprises OH and/or H₂O. In the case of a MOR resist layer 215, the presence of OH and/or H₂O can increase the cross-linking within the resist layer 215. As such, a smaller dose of EUV electromagnetic radiation is needed for the resist layer 215 in order to provide the desired contrast.

In an embodiment, the underlayer 211 may be tuned to selectively release the species 214 into the resist layer 215 through a combination of the EUV exposure and curing process. For example, the underlayer 211 may not release OH and/or H₂O at an elevated temperature in an as-deposited state (i.e., before exposure). However, during and/or after EUV exposure, the underlayer 211 may release the species 214 when brought to an elevated temperature (e.g., around 160° C. or above). In an embodiment, the release of the species 214 may be optimized between approximately 160° C. and approximately 210° C. Bringing the underlayer 211 to the elevated temperature may sometimes be referred to as the curing process. Other embodiments may include a cure that includes heating the device 200 and/or applying a UV treatment to the patterning stack 210. The amount of OH and/or H₂O that is released may also be modulated by controlling a thickness of the underlayer 211. The amount of OH and/or H₂O that is released may also be modulated through control of the concentrations of one or more of the silicon, oxygen, hydrogen, and/or carbon within the underlayer 211. Further, the ability to control the amount of OH and/or H₂O that is released can be used to modify the adhesion strength between the underlayer and the resist layer 215, control the LER, and/or control the LWR.

Accordingly, the species 214 is only released from the exposed regions of the underlayer 211, which allows diffusion of the species 214 into only the exposed resist regions 217 that directly overly the exposed regions 213 of the underlayer 211. The addition of the species 214 to only the exposed regions of the resist layer 215 allows for an improved contrast between exposed resist regions 217 and the unexposed resist regions 216. This leaves the unexposed resist regions 216 less likely to cross-link, and the contrast of the resist layer 215 is improved. Accordingly, overall EUV dosage can be reduced, and throughput is improved.

Referring now to FIG. 2C, a cross-sectional illustration of the device 200 after the resist layer 215 is developed is shown, in accordance with an embodiment. The developing process may result in the removal of the unexposed resist regions 216. Due to the improved contrast performance of the resist layer 215 resulting from the selective release of species 214, the sidewalls 221 of the pattern 218 have a lower surface roughness than previous patterning stack systems. Additionally, the presence of scum at the bottom of the pattern 218 is reduced. As such, a top surface 224 of the unexposed regions 212 of the underlayer 211 is substantially exposed. Accordingly, such a patterning stack 210 allows for overall reductions in the EUV dose while still maintaining low LER, low LWR, and/or high LCDU. In an embodiment, the development of the resist layer 215 may be implemented with a dry develop process (e.g., a thermal etch, a plasma etch, etc.). In such an embodiment, the dry develop process may be implemented within the same cluster tool that comprises the deposition chamber used to deposit the patterning stack 210.

Referring now to FIG. 2D, a cross-sectional illustration of the device 200 after the pattern 218 in the resist layer 215 is transferred into the underlayer 211 with an etching process is shown, in accordance with an embodiment. As shown, the underlayer 211 will also have sidewalls 223 that have a low roughness due to the low roughness of the sidewalls 221 in the resist layer 215. Since there is little (or no) scum, the pattern 218 transfer process is more efficient, and cleaning operations after etching may not be necessary. Accordingly, as CDs continue to shrink in advanced semiconductor devices, enhanced LER, LWR, and/or LCDU will significantly improve overall device 200 performance. In an embodiment, the pattern 218 transfer process may be implemented with a dry etching process (e.g., a thermal etch, a plasma etch, etc.). In such an embodiment, the dry etching process may be implemented within the same tool used for the resist layer 215 development. Further, the dry etching for pattern 218 transfer into the underlayer 211 may be implemented in the cluster tool that incorporates the deposition chamber used to deposit the patterning stack 210.

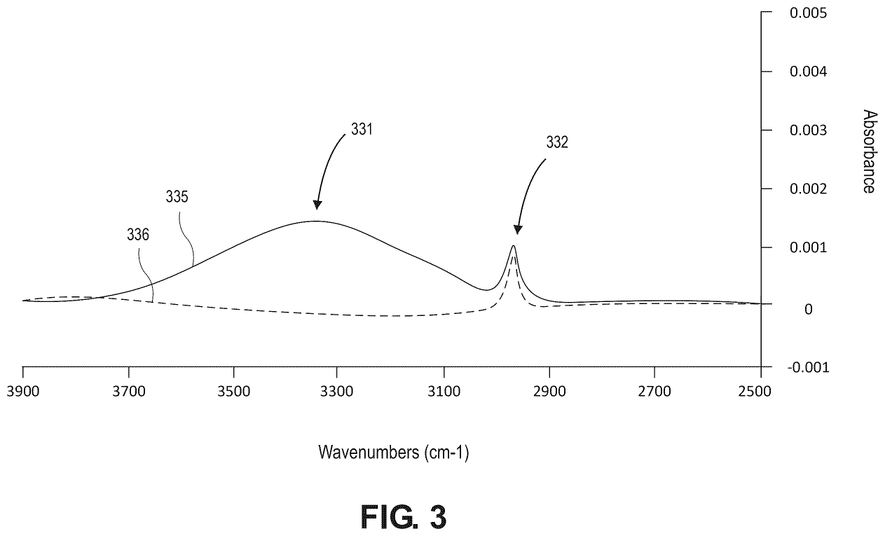

Referring now to FIG. 3, a graph showing the chemical change in an underlayer that is used in the patterning stack 210 of FIGS. 2A-2D is shown, in accordance with an embodiment. More particularly, FIG. 3 is a Fourier transform infrared spectroscopy (FTIR) graph of an as deposited underlayer 335 and an underlayer 336 after EUV exposure and cure.

As shown, the as deposited underlayer 335 includes a plurality of peaks, such as a first peak 331 and a second peak 332, that indicate the presence of different chemical species and/or molecules. For example, the first peak 331 represents the presence of Si—OH, and the second peak 332 represents the presence of Si—CH₃. However, in the plot of the underlayer 336 after EUV exposure and cure, the first peak 331 (i.e., Si—OH) is eliminated.

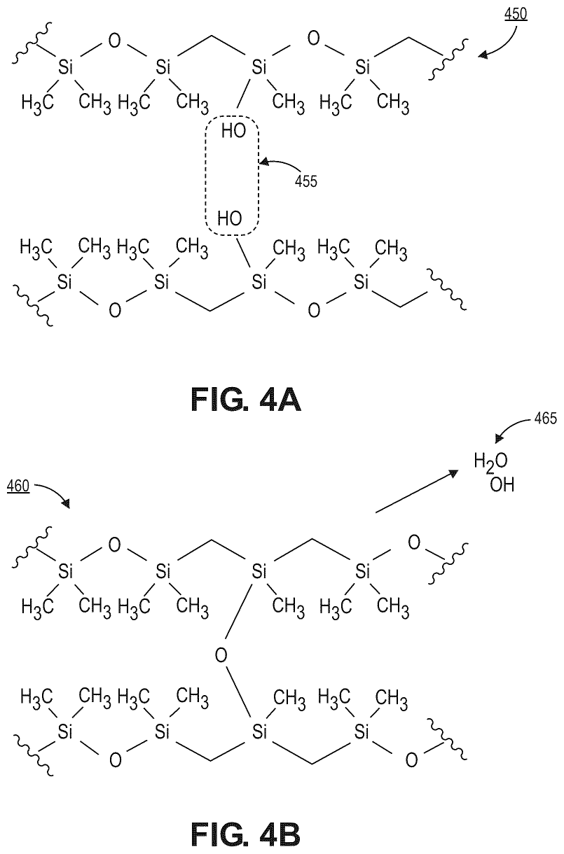

Accordingly, it is to be appreciated that the hydrogen is leaving the underlayer 336 after EUV exposure and cure. As will be illustrated in FIGS. 4A and 4B, oxygen is also released during the EUV exposure and cure. The released combination of oxygen and hydrogen (e.g., in the form of OH and/or H₂O) may diffuse into the overlying resist layer in order to participate in the cross-linking reaction. Accordingly, the overall EUV dose for resist layer is reduced since additional species will be provided that can augment the cross-linking reaction in order to improve contrast in the resist layer.

Referring now to FIGS. 4A and 4B, schematic illustrations of an exemplary chemical structure of the underlayer and the resulting cross-linking reaction are shown, in accordance with an embodiment. In the illustrated embodiment, one particular polymer material is shown. However, it is to be appreciated that other polymer chains with —OH terminated chains may be used. Particularly, the cross-linking reaction of the polymers may primarily occur at the —OH terminated chains in order to release OH and/or H₂O.

Referring now to FIG. 4A, a schematic illustration of an underlayer material 450 is shown, in accordance with an embodiment. In an embodiment, the underlayer material 450 may comprise a plurality of polymer chains with —OH terminations 455. In some embodiments, the —OH terminations may be provided off of silicon. Though, the —OH terminations may be provided as a branch off of any of the elements along the main chain or branches of the polymer. For example, the —OH terminations may extend from silicon, carbon, or oxygen. In the embodiment shown in FIG. 4A, the underlayer material 450 may comprise silicon, oxygen, carbon, and hydrogen. Though, some embodiments may also include underlayer materials 450 with other elements. The particular polymer chain structure shown is exemplary in nature. For example, a linear chain with relatively short branches (e.g., CH₃ branches) is shown in FIG. 4A. Though, other embodiments may include underlayer materials 450 that include longer branches, more branches, fewer branches, cyclic regions, and/or the like.

Referring now to FIG. 4B, a schematic illustration of a cross-linked underlayer material 460 is shown, in accordance with an embodiment. As shown, the —OH terminations 455 of opposing chains are reacted to cross-link the opposing chains together. For example, the two-OH terminations 455 react to leave behind an oxygen atom between a pair of silicon atoms on the opposing chains. The remaining oxygen atom and the two hydrogen atoms from the reaction may leave as a species 465 in the form of OH and/or H₂O. The particular cross-linking reaction shown in FIG. 4B, may be referred to as silanol condensation reaction. In an embodiment, the driving force that enables the cross-linking reaction may include the EUV exposure. Embodiments may also improve cross-linking through a curing process (e.g., at a temperature of 160° C. or above and/or a UV treatment).

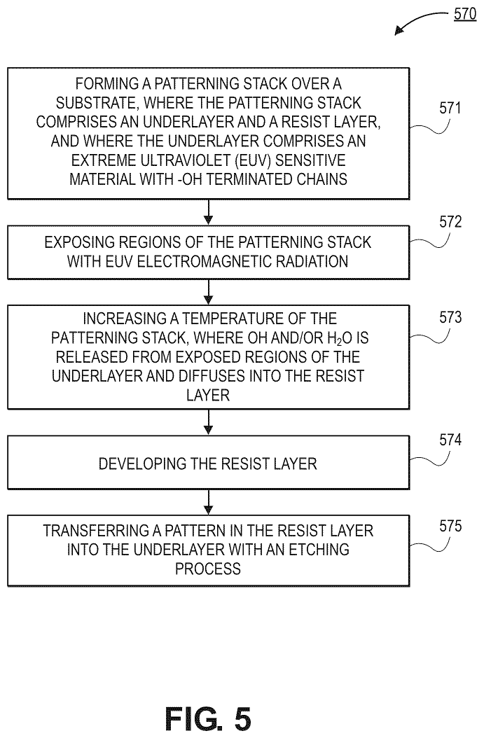

Referring now to FIG. 5, a flow diagram of a process 570 for patterning a patterning stack is shown, in accordance with an embodiment. In an embodiment, the process 570 may begin with operation 571, which comprises forming a patterning stack over a substrate. In an embodiment, the patterning stack comprises an underlayer and a resist layer over the underlayer. In an embodiment, the underlayer comprises an EUV sensitive material with —OH terminated chains. In an embodiment, the underlayer comprises silicon, oxygen, carbon, and hydrogen. Further, the underlayer may be substantially free from nitrogen. The underlayer may also be a flowable polymer. In some instances, the underlayer and the resist layer are deposited over the substrate with a CVD process. In an embodiment, the resist layer comprises an EUV sensitive material, such as a MOR. For example, the MOR may be a tin-oxide based resist.

In an embodiment, the process 570 may continue with operation 572, which comprises exposing regions of the patterning stack with EUV electromagnetic radiation. In an embodiment, the patterning may result in the formation of exposed regions and unexposed regions in the resist layer and the underlayer. In an embodiment, the EUV exposure to the underlayer may drive a cross-linking reaction. For example, the cross-linking reaction may be a silanol condensation reaction. In such an embodiment, the cross-linking is initiated at the —OH terminations to provide oxygen links between opposing polymer chains. The cross-linking reaction may also release OH and/or H₂O. Since EUV exposure drives the reaction, only the exposed regions of the underlayer will release OH and/or H₂O.

In an embodiment, the process 570 may continue with operation 573, which comprises increasing a temperature of the patterning stack. In an embodiment, the temperature of the patterning stack is increased to at least 160° C. In an embodiment, the increased temperature allows for released OH and/or H₂O from exposed regions of the underlayer to diffuse into the resist layer. More particularly, the OH and/or H₂O may only diffuse into the overlying exposed regions of the resist layer. As such, the cross-linking process in the exposed regions will proceed faster, and the EUV dose is reduced.

In an embodiment, the process 570 may continue with operation 574, which comprises developing the resist layer. The developing process may be a dry process (e.g., a thermal etch or a plasma etch). In an embodiment, the developing process may be done in a cluster tool that comprises the deposition chamber used to deposit the patterning stack.

In an embodiment, the process 570 may continue with operation 575, which comprises transferring a pattern of the developed resist layer into the underlayer with an etching process. The pattern transfer process may be a dry etching process. The pattern transfer process and the developing process may be implemented in the same chamber. Further, the pattern transfer process may be done in a cluster tool that comprises the deposition chamber used to deposit the patterning stack.

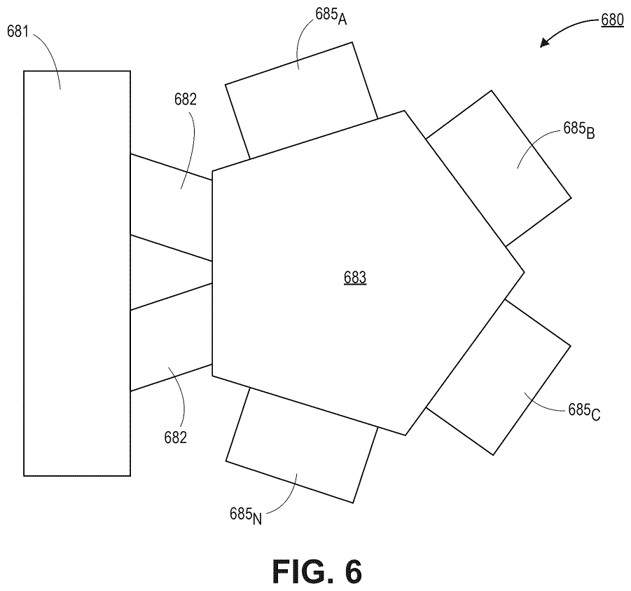

Referring now to FIG. 6, a plan view illustration of a cluster tool 680 that may be used to implement one or more processes for patterning a patterning stack with an underlayer that comprises-OH terminated chains is shown, in accordance with an embodiment. In an embodiment, the cluster tool 680 may comprise an equipment front end module (EFEM) 681. The EFEM 681 may be used to receive substrates (e.g., wafers) from other locations within a factory (i.e., a fab). The substrates may be delivered to the EFEM 681 in a front opening unified pod (FOUP) or the like. In an embodiment, the EFEM 681 may transfer the substrates to a central interface 683 through one or more load locks 682. The central interface 683 may be at sub-atmospheric pressure in order to allow for substrates to remain in a low pressure (e.g., vacuum) environment during processing.

In an embodiment, the central interface 683 may be coupled to a plurality of chambers 685A-685N. While four chambers 685 are shown in FIG. 6, it is to be appreciated that any number of chambers 685 may be used in other embodiments. In an embodiment, the plurality of chambers 685A-685N may include different types of chambers for implementing the formation of a patterning stack and the subsequent patterning of the patterning stack. For example, a first chamber 685A may include a deposition chamber, such as a CVD chamber. The first chamber 685A may be used to deposit the underlayer and the resist layer over the substrate. In an embodiment, a second chamber 685B may be an etching chamber that is used for developing the resist layer after EUV exposure and for transferring the pattern into the underlayer.

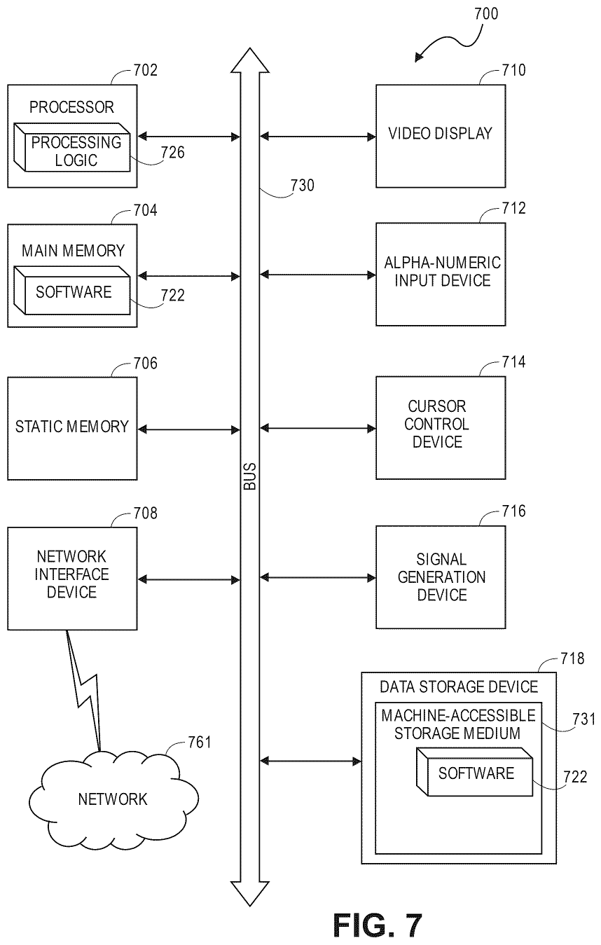

Referring now to FIG. 7, a block diagram of an exemplary computer system 700 of a processing tool is illustrated in accordance with an embodiment. In an embodiment, computer system 700 is coupled to and controls processing in the processing tool. Computer system 700 may be connected (e.g., networked) to other machines in a Local Area Network (LAN), an intranet, an extranet, or the Internet. Computer system 700 may operate in the capacity of a server or a client machine in a client-server network environment, or as a peer machine in a peer-to-peer (or distributed) network environment. Computer system 700 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 700, the term “machine” shall also be taken to include any collection of machines (e.g., computers) that individually or jointly execute a set (or multiple sets) of instructions to perform any one or more of the methodologies described herein.

Computer system 700 may include a computer program product, or software 722, having a non-transitory machine-readable medium having stored thereon instructions, which may be used to program computer system 700 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 700 includes a system processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

System processor 702 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 702 may also be one or more special-purpose processing devices such as an application specific integrated circuit (ASIC), a field programmable gate array (FPGA), a digital signal system processor (DSP), network system processor, or the like. System processor 702 is configured to execute the processing logic 726 for performing the operations described herein.

The computer system 700 may further include a system network interface device 708 for communicating with other devices or machines. The computer system 700 may also include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium 731 (or more specifically a computer-readable storage medium) on which is stored one or more sets of instructions (e.g., software 722) embodying any one or more of the methodologies or functions described herein. The software 722 may also reside, completely or at least partially, within the main memory 704 and/or within the system processor 702 during execution thereof by the computer system 700, the main memory 704 and the system processor 702 also constituting machine-readable storage media. The software 722 may further be transmitted or received over a network 761 via the system network interface device 708. In an embodiment, the network interface device 708 may operate using RF coupling, optical coupling, acoustic coupling, or inductive coupling.

While the machine-accessible storage medium 731 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method, comprising:
forming a patterning stack over a substrate, wherein the patterning stack comprises:
an underlayer over the substrate, wherein the underlayer comprises an extreme ultraviolet (EUV) sensitive material with —OH terminated chains; and
a resist layer over the underlayer;
exposing regions of the patterning stack with EUV electromagnetic radiation;
releasing OH and/or H₂O from exposed regions of the underlayer and diffusing the OH and/or H₂O into the resist layer; and
developing the resist layer.

2. The method of claim 1, wherein the underlayer comprises silicon, oxygen, carbon, and hydrogen.

3. The method of claim 1, wherein the underlayer is a curable polymer.

4. The method of claim 1, wherein a temperature of the patterning stack is increased to at least 160° C.

5. The method of claim 1, wherein the underlayer and the resist layer are formed with a chemical vapor deposition (CVD) process.

6. The method of claim 5, further comprising:
transferring a pattern of the developed resist layer into the underlayer with an etching process.

7. The method of claim 6, wherein the CVD process and the etching process are implemented in a single cluster tool.

8. The method of claim 1, wherein the resist layer comprises a metal oxide resist (MOR).

9. The method of claim 1, wherein unexposed regions of the underlayer do not release OH and/or H₂O.

10. The method of claim 1, wherein nitrogen is not integrated into the underlayer.

11. A patterning stack for extreme ultraviolet (EUV) lithography, comprising:
a substrate;
an underlayer over the substrate, wherein the underlayer comprises a first EUV sensitive material with —OH terminated chains; and
a resist layer over the underlayer, wherein the resist layer is a second EUV sensitive material.

12. The patterning stack of claim 11, wherein the underlayer comprises silicon, oxygen, carbon, and hydrogen.

13. The patterning stack of claim 11, wherein the underlayer is a curable polymer.

14. The patterning stack of claim 11, wherein the resist layer is a metal oxide resist (MOR).

15. The patterning stack of claim 11, wherein the underlayer is substantially free of nitrogen.

16. The patterning stack of claim 11, wherein the underlayer releases OH and/or H₂O in response to EUV exposure.

17. The patterning stack of claim 11, wherein the underlayer is cross-linked during EUV exposure through a silanol condensation process.

18. A method, comprising:
forming a patterning stack over a substrate, wherein the patterning stack comprises:
an underlayer over the substrate, wherein the underlayer comprises an extreme ultraviolet (EUV) sensitive material comprising silicon, oxygen, carbon, and hydrogen with —OH terminated chains; and
a resist layer over the underlayer, wherein the resist layer is a metal oxide resist (MOR);
exposing regions of the patterning stack with EUV electromagnetic radiation;
curing the patterning stack, wherein exposure and curing drives a silanol condensation cross-linking process in the underlayer that releases OH and/or H₂O that diffuses into the resist layer; and
developing the resist layer.

19. The method of claim 18, further comprising:
transferring a pattern in the developed resist layer into the underlayer with an etching process.

20. The method of claim 18, wherein the curing includes bringing a temperature of the patterning stack to at least 160° C.
